(19) United States
(12) Patent Application Publication
(10) Pub. No.: US 2005/0167796 A1
(43) Pub. Date: Aug. 4, 2005

(54) Miniaturised surface mount optoelectronic component

(76) Inventors: Kheng Chiong Tay, Melaka (MY); Khin Shin Lai, Melaka (MY); Tek Beng Low, Melaka (MY)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/765,841

(22) Filed: Jan. 29, 2004

(51) Int. Cl. H01L 23/02

(52) U.S. Cl. 257/678

(57) ABSTRACT

The invention relates to a miniaturised surface mount optoelectronic component. An electrically conductive material (1) preferably metal frame is used to serve as the base for the assembly. Optionally a cavity (2) may be formed within this electrically conductive base material to serve as a reflector cup. An optoelectronic chip (3) is mounted within this cavity. The whole base material is then encapsulated with a hard transparent or translucent resin material (4) so that optical radiation may be transmitted or received via this medium. Electrical connection(s) between the chip and the base material is provided by a metallic wire or wires (6).

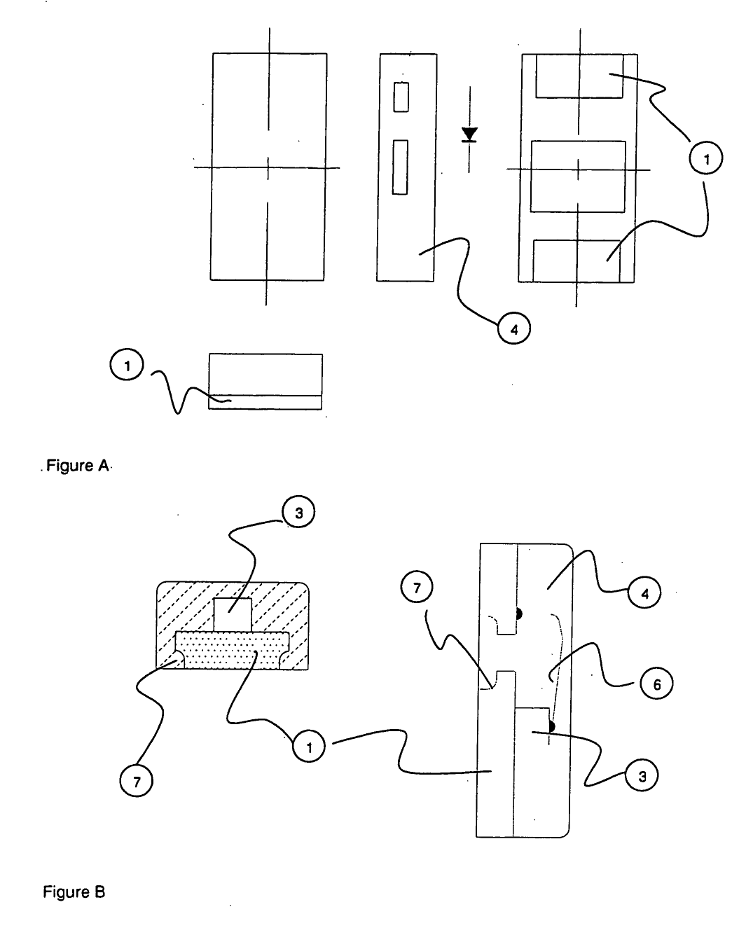

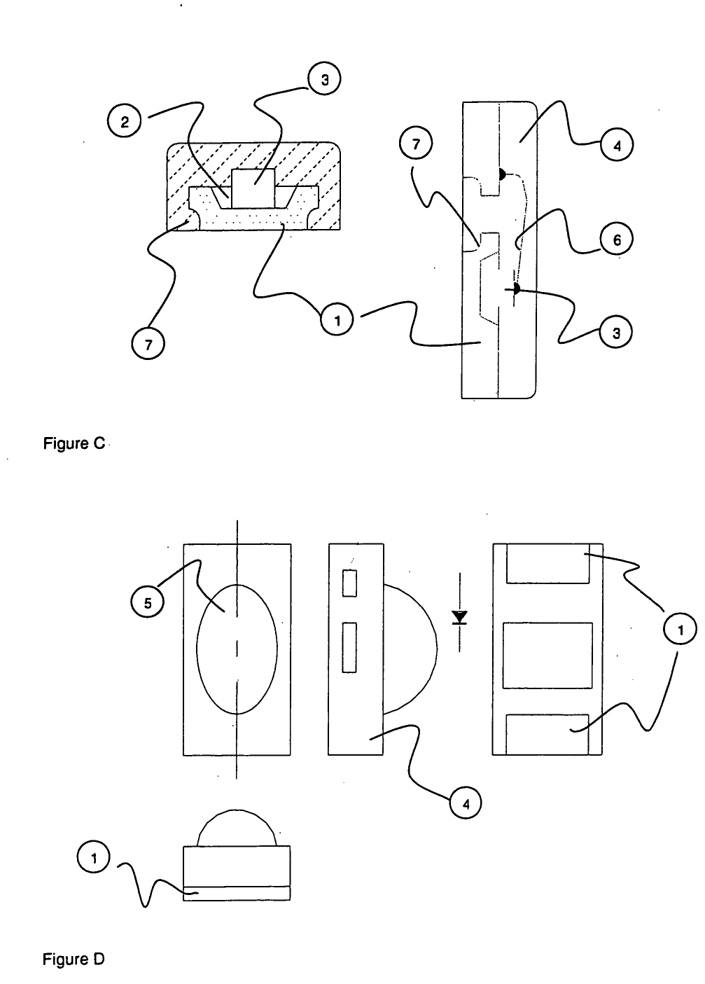

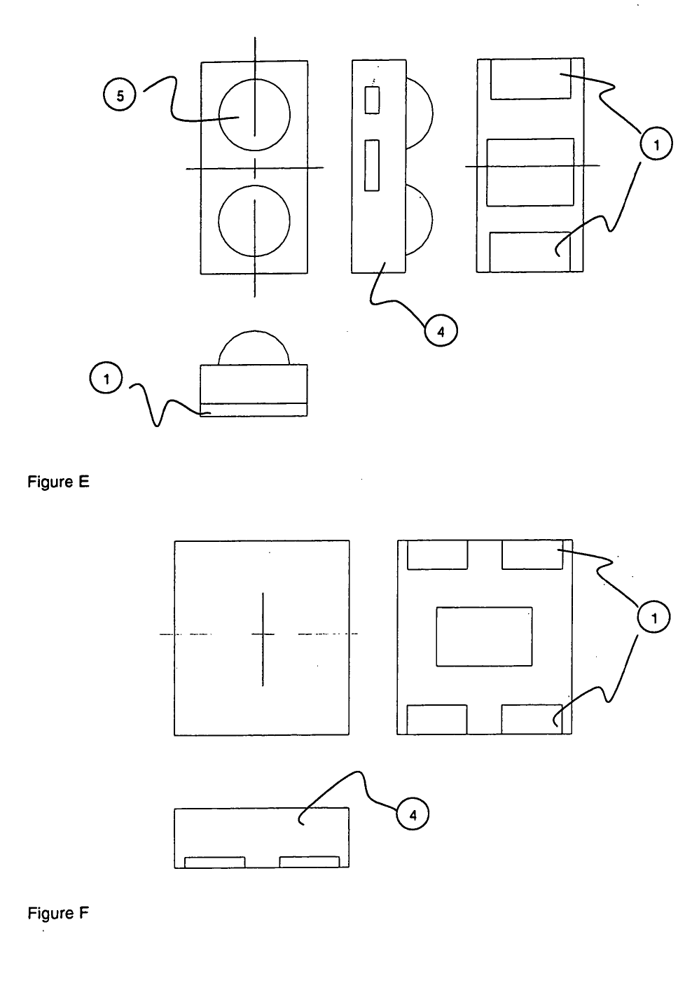

### FIELD OF THE INVENTION

The present invention relates to a miniaturised surface mount optoelectronic component.

### BACKGROUND ART

There are many different types of designs for surface mount optoelectronic components available in the industry today. In general, they can be divided into two major groups. The first major group is related to a PCB based surface mount optoelectronic component. This type of optoelectronic component is being widely used in less demanding applications such as consumer electronics. The prior art discloses several examples of such components. An example is the 0603 ChipLED products available today. A PCB is used as the base material. Metalised tracks and pads are provided for chip attachment, wire bonding and terminal soldering. This optoelectronic component design provides an easy means to achieving small package outline and low height profile. However, this design has its limitations. Power dissipation is limited due to the poor thermal conductivity of the PCB material. Products are also not robust to moisture and high temperature.

The second group is related to a lead-frame based surface mount optoelectronic component. This type of optoelectronic component is widely used in more stringent applications such as automotive and industrial application. A classic example is the PLCC2 package. In U.S. Pat. No. 6,459,130, described by Arndt et al., the optoelectronic component comprising a lead-frame is used to serve as the base assembly material. Plastic is insert molded onto the frame to provide the package housing and reflective surface. Clear or diffused resin is subsequently casted into a cavity to allow for radiation transmission. The lead-frame protrudes out from the housing and is bent and formed to serve as soldering terminals. This type of optoelectronic component design provides good robustness and also good thermal dissipation capability. However, due to processing limitation, the degree of miniaturisation possible is limited. The need to have a reflective housing and ‘formed’ soldering terminals limits the extent the optoelectronic components can be miniaturised.

### SUMMARY OF THE INVENTION

Accordingly, there is provided a miniaturised surface mount optoelectronic component, said optoelectronic component comprising an electrically conductive material, said material is used as a base material for an assembly, at least an optoelectronic chip, said optoelectronic chip is mounted on said base, and an electrical connection between said optoelectronic chip and said electrically conductive material by a wiring means, wherein said base material is encapsulated with a hard transparent or translucent resin material to enable optical radiation to be transmitted or received via said optoelectronic component.

The component is designed to serve highly compact applications where size is a very critical feature. The invention is also capable of higher heat dissipation due to the thick base material used to serve as the heat sink for the design.

The present invention consists of certain novel features and a combination of parts hereinafter fully described and illustrated in the accompanying drawings, and particularly pointed out in the appended claims, it being understood that various changes in the details may be made without departing from the scope of the invention or sacrificing any of the advantages of the present invention.

### BRIEF DESCRIPTION OF THE DRAWINGS

For the purpose of facilitating an understanding of the invention, there is illustrated in the accompanying drawings the preferred embodiments thereof, from an inspection of which, when considered in connection with the following description, the invention, its construction and operation, and many of its advantages should be readily understood and appreciated.

FIG. A is a two-dimensional view of the miniaturised surface mount optoelectronic component according to the preferred embodiments of the present invention. The top, bottom and side view of the invention is as illustrated;

FIG. B is a cross-sectional view of the miniaturised surface mount optoelectronic component according to the preferred embodiments of the present invention depicting the internal structure of the optoelectronic component;

FIG. C is a cross-sectional view of the miniaturised surface mount optoelectronic component according to the preferred embodiments of the present invention with an optional reflector cup;

FIG. D is a two-dimensional view of the miniaturised surface mount optoelectronic component according to the preferred embodiments of the present invention with a lens structure.

FIG. E is a two-dimensional view of the miniaturised surface mount optoelectronic component according to the preferred embodiments of the present invention with a multiple lens structure;

FIG. F is a two-dimensional package drawing with multiple soldering terminals.

### DETAILED DESCRIPTION OF THE PREFERRED EMBODIMENTS

The present invention relates to a miniaturised surface mount optoelectronic component. Hereinafter, this specification will describe the optoelectronic component according to the preferred embodiments and by referring to the accompanying drawings. However, it is to be understood that limiting the description to the preferred embodiments of the invention and with reference to the accompanying drawings is merely to facilitate discussion of the present invention and it is envisioned that those skilled in the art may devise various modifications and equivalents without departing from the scope of the appended claims.

With reference to the drawings, the optoelectronic component is based on the surface mount technology. An electrically conductive material (1), preferably a metal frame, is used to serve as the base for the assembly. An optoelectronic chip or chips (3) is (are) then mounted on the base material or optionally within the cavity. The whole base material is then encapsulated with a hard transparent or translucent resin material (4) so that optical radiation may be transmitted or received via this medium. The resin encapsulation will protect the optoelectronic chip from the external environment.

Soldering terminals (8) to the external sub-systems, such as PCB, are provided by the base material itself. The soldering terminals (8) are part of the electrically conductive frame (1) and are positioned at the bottom and side portions of the optoelectronic component. The terminals (8) are located on the same horizontal datum as the encapsulation material. Furthermore, the soldering terminals (8) do not extend beyond the outline of the component which is formed by the encapsulation material (4). Different numbers of soldering terminals in different configurations are possible, depending on application needs, as illustrated by the drawings. No extra mechanical forming processes are necessary to create the soldering terminals. These features allow small outline packages and also packages with high number of soldering terminals to be implemented without being constrained by the forming process requirements and dimensional limitation.

The electrically conductive frame (1), preferably metal, is strongly embedded into the resin material (4) by a series of ‘grooves’ and ‘wings’ (7) crafted onto the frame. These features will enhance the anchorage of the frame and consequently minimise the occurrence of de-lamination between resin and the frame. This is important because de-lamination has always been one of the root causes of product failure.

In another form of embodiment, a cavity (2) may be formed within the electrically conductive frame. This cavity may be formed by means of stamping, etching or micro-drilling. An optoelectronic chip may then be placed within this cavity, wherein the cavity operates as a reflector to collimate the radiation emitted by the chip.

In another form of embodiment, a lens structure (5) may be incorporated as part of the encapsulation material. This can be achieved by implementing the relevant mold die design for the encapsulation process. Different lens designs can be used to attain the desired spectral radiation pattern.

In another embodiment, a multiple lens structure (5) may also be incorporated to achieve different functional purposes. Electrical connection(s) between the chip and the base material is provided by a metallic wire or wires (6).

While in the foregoing specification this invention has been described in relation to certain preferred embodiments thereof, and many details have been set forth for purpose of illustration, it will be apparent to those skilled in the art, that the invention is susceptible to additional embodiments and that certain of the details described herein can be varied considerably without departing from the basic principles of the invention.

1. An optoelectronic component based on a surface mount technology, said optoelectronic component comprising:
an electrically conductive frame to form a base for an assembly;
at least one optoelectronic chip mounted on said base;
an electrical connection between said optoelectronic chip and said electrically conductive frame by wiring means; and
soldering terminals which are part of said electrically conductive frame and are exposed at bottom and side portions of said component;
wherein said electrically conductive frame is encapsulated with a translucent material to enable optical radiation to be transmitted or received via said optoelectronic component; and
wherein said soldering terminals do not extend beyond an outline of said encapsulation material.

2-9. (canceled)

10. The optoelectronic component as claimed in claim 1, wherein said electrically conductive frame is made of a metal.

11. The optoelectronic component as claimed in claim 1, wherein a lens structure is incorporated as part of said encapsulation material.

12. The optoelectronic component as claimed in claim 1, wherein a multiple lens structure is incorporated as part of said encapsulation material.

13. The optoelectronic component as claimed in claim 1, wherein a cavity is formed within said electrically conductive frame and is used to attach said optoelectronic chip within said cavity and serve as a reflector.

14. The optoelectronic component as claimed in claim 1, wherein said electrically conductive frame is crafted with a series of grooves and wings to enhance anchorage and minimize an occurrence of de-lamination.
